(19) United States
(12) Patent Application Publication
(10) Pub. No.: US 2025/0054781 A1
(43) Pub. Date: Feb. 13, 2025

(54) ARRAY-TYPE MEGASONIC CLEANING DEVICE FOR CLEANING WAFERS

(71) Applicant: HANGZHOU SIZONE ELECTRONIC TECHNOLOGY INC, Zhejiang (CN)

(72) Inventors: Xiaoyu XU, Zhejiang (CN); Yuansi YANG, Zhejiang (CN)

(73) Assignee: HANGZHOU SIZONE ELECTRONIC TECHNOLOGY INC, Zhejiang (CN)

(21) Appl. No.: 18/720,666

(22) PCT Filed: Nov. 9, 2022
(86) PCT No.: PCT/CN2022/130779

§ 371 Date: Jun. 17, 2024

(30) Foreign Application Priority Data
Oct. 19, 2021 (CN) 202111217131.1

(51) Int. Cl. H01L 21/67

(52) U.S. Cl. CPC H01L 21/67057

(57) ABSTRACT

An array-type megasonic cleaning device for cleaning wafers (5), comprising: a cleaning tank (3); and a first driving shaft (1) and a second driving shaft (2) that are arranged in parallel with each other in the cleaning tank (3), and have an axial length of 60-350 mm, wherein at least two first clamping grooves (11) are formed on the first driving shaft (1) in a length direction, at least two second clamping grooves (21) are formed on the second driving shaft (2) in a length direction, and the second clamping grooves (21) are arranged corresponding to the first clamping grooves (11); the plurality of wafers (5) are respectively placed by means of the cooperation between the first clamping grooves (11) and the second clamping grooves (21); and the first driving shaft (1) and the second driving shaft (2) rotate in the same direction

### TECHNICAL FIELD

The invention belongs to the field of fabrication of semiconductor integrated circuit chips, and particularly relates to an array-type megasonic cleaning device for cleaning wafers.

### DESCRIPTION OF RELATED ART

Process units for cleaning, including a megasonic cleaning unit, a brushing unit and a drying unit, function for removing residual polishing fluid and other contaminant particles from wafers. According to the principle of megasonic cleaning, a high-frequency oscillating current from a high-frequency AC power source is converted by a transducer into mechanical vibration waves, which are then transmitted into a cleaning medium to produce cavitation and acoustic wave flow in the liquid to remove particles attached to the surface of the wafers. Megasonic cleaning causes less damage to the surface of the wafers and can remove particles less than 0.2 microns.

Problems in the prior art: Currently, there has been a megasonic cleaning scheme disclosed by Chinese patent CN206966220U, where wafers are placed in a cleaning tank, separated by partition plates and cleaned by means of megasonic waves. In this scheme, the wafers remain static in the cleaning tank, leading to poor cleaning uniformity and consistency.

At present, the requirement for the wafer output per unit time of chemical mechanical planarization equipment is becoming increasingly higher, and the working efficiency of the conventional single-tank single-wafer megasonic cleaning mode cannot meet the cleaning demand anymore. The use of multiple single-wafer megasonic cleaning tanks for improving the wafer output occupies too much space, extends the transfer distance, decreases the transfer efficiency, and thus cannot meet the production demand.

### SUMMARY

In order to overcome the shortcomings of the prior art, the invention provides an array-type megasonic cleaning device for cleaning wafers, which can clean multiple wafers simultaneously to reach a higher wafer output and ensure the cleaning uniformity and consistency.

A technical solution adopted by the invention to solve the technical problem is: an array-type megasonic cleaning device for cleaning wafers, comprising:
a cleaning tank with cleaning liquid and a megasonic generating device inside; and
a first driving shaft and a second driving shaft that are arranged in parallel with each other in the cleaning tank and are capable of rotating circumferentially about their own center axes under the drive of a drive unit;
wherein the first driving shaft and the second driving shaft have an axial length of 60-350 mm;
at least two first clamping grooves are formed on the first driving shaft in a length direction, at least two second clamping grooves are formed on the second driving shaft in a length direction, and the second clamping grooves are arranged corresponding to the first clamping grooves;
a plurality of wafers are respectively placed by means of the cooperation of the first clamping grooves and the second clamping grooves, and the first driving shaft and the second driving shaft are configured to be respectively located on two sides of the center axis of the wafers;
the first driving shaft and the second driving shaft rotate in a same direction, and then the plurality of wafers can be driven, by friction, to rotate simultaneously to be cleaned.

The array-type megasonic cleaning device for cleaning wafers further comprises: a driven shaft provided with at least two limiting grooves, wherein the limiting grooves are located in a same vertical plane as the first clamping grooves and the second clamping grooves, and edges of the wafers fall into the limiting grooves.

According to the invention, a plurality of wafers can be placed in the cleaning tank to be cleaned simultaneously, such that under the premise of ensuring the same cleaning efficiency, the area occupied by the cleaning tank is minimized and the consistency of the cleaning effect of the wafers is ensured. Less cleaning liquid in the cleaning tank will be used for cleaning a multiple wafers are cleaned, thereby reducing costs. For wafer transfer, a set of robot arms can be used to pick and place multiple wafers at the same time, so the wafers can be transferred more conveniently.

Further, the driven shaft is configured to be located under the wafers and deviates from the center axis of the wafers. The distance between the megasonic cleaning device and the wafers 5 is relatively short, thus ensuring a better cleaning effect.

Further, gaps are formed between inner walls of the limiting grooves and the wafers. In this way, the frictional resistance that rotating wafers are subject to is reduced. The limiting grooves can prevent excessive shaking of the wafers.

Further, the side surfaces of the limiting grooves are in contact with the wafers to drive the driven shaft to rotate; the driven shaft is externally connected to a rotation speed detection unit to monitor a rotation speed of the wafers; gaps are formed between bottom surfaces of the limiting grooves and the wafers. The wafers drive the driven shaft to rotate synchronously by means of the limiting grooves, such that the rotation speed of the wafers can be monitored easily; the bottom surfaces of the limiting grooves are not in contact with the wafers, such that the processing accuracy is reduced and processing is facilitated.

Further, rotation speeds of the first driving shaft and the second driving shaft are the same.

Further, one end of the first driving shaft and/or the second driving shaft is connected to a side wall of the cleaning tank, and the other end of the first driving shaft and/or the second driving shaft is connected to the drive unit; alternatively, one end of the first driving shaft and/or the second driving shaft is suspended in the cleaning tank, and the other end of the first driving shaft and/or the second driving shaft is connected to the drive unit.

Further, the driven shaft comprises a first shaft body and a second shaft body, the first shaft body and the second shaft body are coaxially arranged, and adjacent ends of the first shaft body and the second shaft body are suspended.

Further, the first driving shaft and/or the second driving shaft comprises a left shaft body and a right shaft body, and the left shaft body and the right shaft body are coaxially arranged and driven by the drive unit to rotate respectively. The left shaft body of the first driving shaft and the left shaft body of the second driving shaft can work together to drive a batch of wafers to rotate to be cleaned; the left shaft body of the second driving shaft and the right shaft body of the second driving shaft can work together to drive another batch of wafers to rotate to be cleaned; the two batches of wafers rotate separately, and the rotation speeds of the two batches of wafers may be different, thereby realizing two different cleaning speeds in one cleaning tank. The cleaning modes are diversified, and using is more flexible.

Further, rotation speeds of the left shaft body and the right shaft body are different.

The invention has the following merits: a plurality of wafers can be placed in the cleaning tank and cleaned simultaneously, such that under the premise of ensuring the same cleaning efficiency, the area occupied by the cleaning tank is minimized and the consistency of the cleaning effect of the wafers is ensured. The requirement for a higher wafer output is met. The wafers rotate in the cleaning tank, thus solving the problem of poor cleaning uniformity and consistency. Less cleaning liquid in the cleaning tank will be used for cleaning multiple wafers, thereby reducing costs. For wafer transfer, a set of robot arms can be used to pick and place a plurality of wafers at the same time, so the wafers can be transferred more conveniently.

### BRIEF DESCRIPTION OF THE DRAWINGS

FIG. 1 is a perspective view of an array-type megasonic cleaning device according to Embodiment 1 of the invention.

FIG. 2 is a top view of the array-type megasonic cleaning device according to Embodiment 1 of the invention.

FIG. 3 is a cross-sectional view of the array-type megasonic cleaning device according to Embodiment 1 of the invention.

FIG. 4 is a longitudinal sectional view of the array-type megasonic cleaning device according to Embodiment 1 of the invention.

FIG. 5 is a perspective view of the array-type megasonic cleaning device without a cleaning tank according to Embodiment 1 of the invention.

FIG. 6 is a top view of the array-type megasonic cleaning device according to Embodiment 2 of the invention.

FIG. 7 is a cross-sectional view of the array-type megasonic cleaning device according to Embodiment 2 of the invention.

FIG. 8 is a perspective view of the array-type megasonic cleaning device without a cleaning tank according to Embodiment 2 of the invention.

### DESCRIPTION OF THE EMBODIMENTS

To allow those skilled in the art to gain a better understand of the technical solutions of the invention, the technical solutions in embodiments of the invention will be clearly and completely described below in conjunction with the accompanying drawings in the embodiments. Obviously, the embodiments in the following description are only part, not all of the embodiments of the invention. All other embodiments obtained by those ordinarily skilled in the art based on the following ones without creative labor should fall within the scope of the invention.

### First Embodiment

An array-type megasonic cleaning device for cleaning wafers comprises:
a cleaning tank 3 with cleaning liquid inside and a megasonic generating device 31 at the bottom;
a first driving shaft 1, arranged in the cleaning tank 3 and capable of rotating circumferentially about its own center axis under the drive of a drive unit 4, the first driving shaft 1 having an axial length of 60-350 mm;
a second driving shaft 2 arranged in the cleaning tank 3 and in parallel with the first driving shaft 1, the second driving shaft 2 being capable of rotating circumferentially about its own center axis under the drive of a drive unit which is or is not the drive unit that drives the first driving shaft 1, the second driving shaft 2 having an axial length of 60-350 mm;
wherein at least two first clamping grooves 11 are formed on the first driving shaft 1 in a length direction;
at least two second clamping grooves 21 are formed on the second driving shaft 2 in the length direction, and the second clamping grooves 21 are arranged corresponding to the first clamping grooves 11. Here, the second clamping grooves 21 correspond to the first clamping grooves 11 in quantity and position. Specifically, the projections of the first clamping grooves 11 on a side wall of the cleaning tank 3 overlap, or at least partially overlap with the projections of the second clamping grooves 21 on the side wall of the cleaning tank 3.

In this way, two or more wafers 5 are respectively placed by means of the cooperation of the first clamping grooves 11 and the second clamping grooves 21. Moreover, the first driving shaft 1 and the second driving shaft 2 are configured to be respectively located on two sides of the center axis of the wafers 5. That is, each wafer 5 is placed on one first clamping grooves 11 and the corresponding second clamping groove 21, and the side wall of the wafer 5 is in contact with the bottom walls of the first clamping groove 11 and the corresponding second clamping groove 21.

The first driving shaft 1 and the second driving shaft 2 rotate in the same direction, and then the wafers 5 can be driven, by friction, to rotate simultaneously. In this way, the wafers 5 can be cleaned while rotating.

The array-type megasonic cleaning device for cleaning wafers may further comprise a driven shaft 6 provided with at least two limiting grooves 63, wherein the limiting grooves 63 are located in a same vertical plane as the first clamping grooves 11 and the second clamping grooves 21. More specifically, the limiting grooves 63 correspond to the first clamping grooves 11 and the second clamping grooves 12 in quantity and position. Edges of the wafers 5 fall into the limiting grooves 63.

The driven shaft 6 is configured to be located under the wafers 5 and deviates from the center axis of the wafers. In this way, the distance between the megasonic cleaning device 31 and the wafers 5 is relatively short, ensuring a better cleaning effect.

Gaps are formed between inner walls of the limiting grooves 63 and the wafers 5 and in this case, gaps are formed between bottom walls of the limiting grooves 63 and side walls of the wafers 5, and gaps are also formed between side walls of the limiting grooves 63 and the surfaces of the wafers 5.

Of course, in another implementation, the side surfaces of the limiting grooves 63 are in contact with the surfaces of the wafers 5 to drive the driven shaft 6 to rotate by virtue of friction; and gaps are formed between bottom surfaces of the limiting grooves 63 and the wafers 5. In this case, the driven shaft is externally connected to a rotation speed detection unit 64. Since the driven shaft 6 is driven by the wafers 5 to rotate synchronously, the rotation speed of the wafers 5 can be indirectly monitored by monitoring the rotation speed of the driven shaft 6.

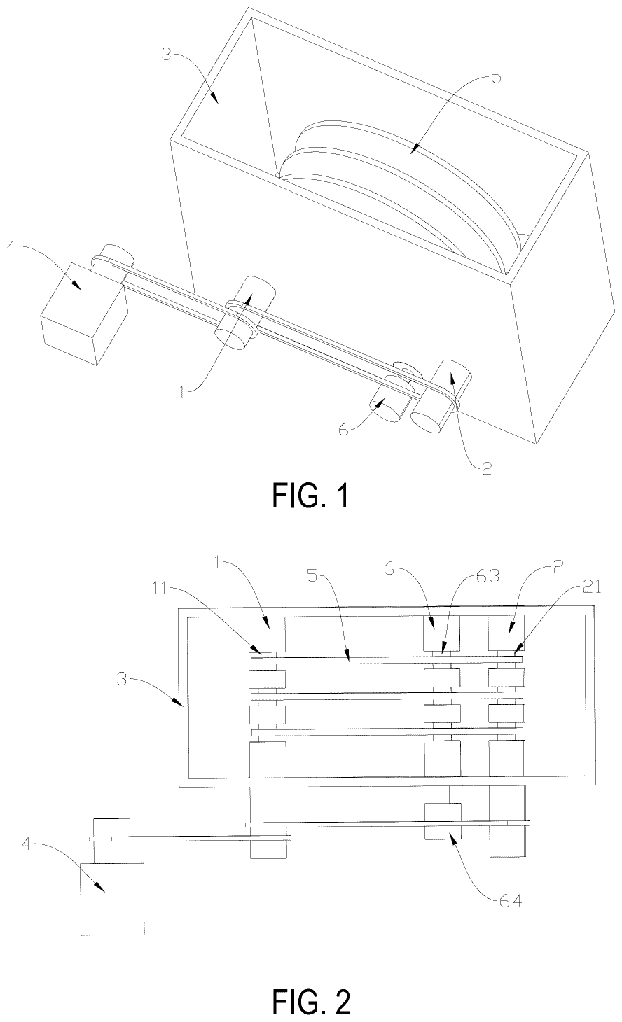

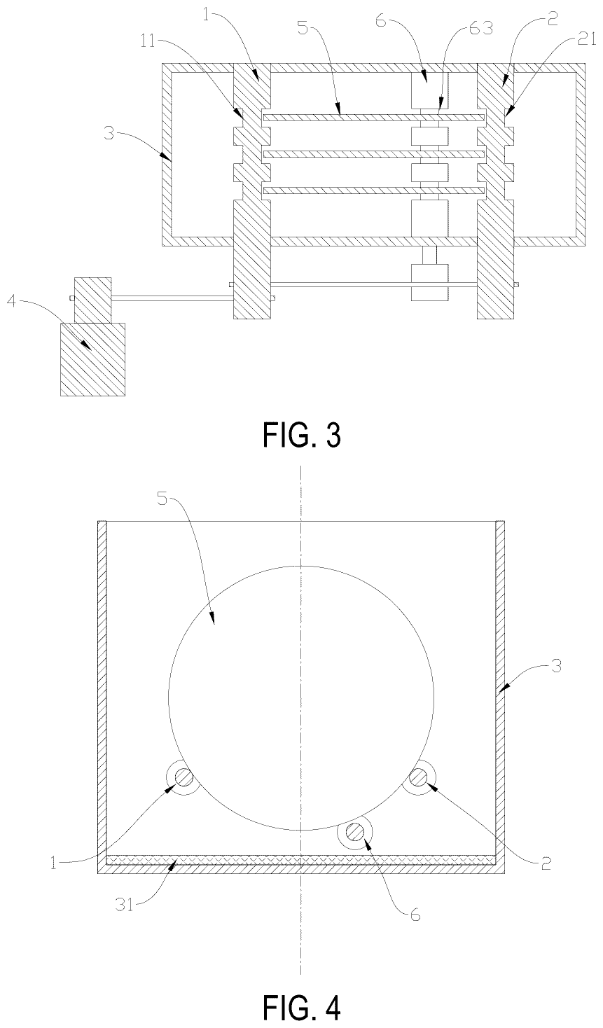

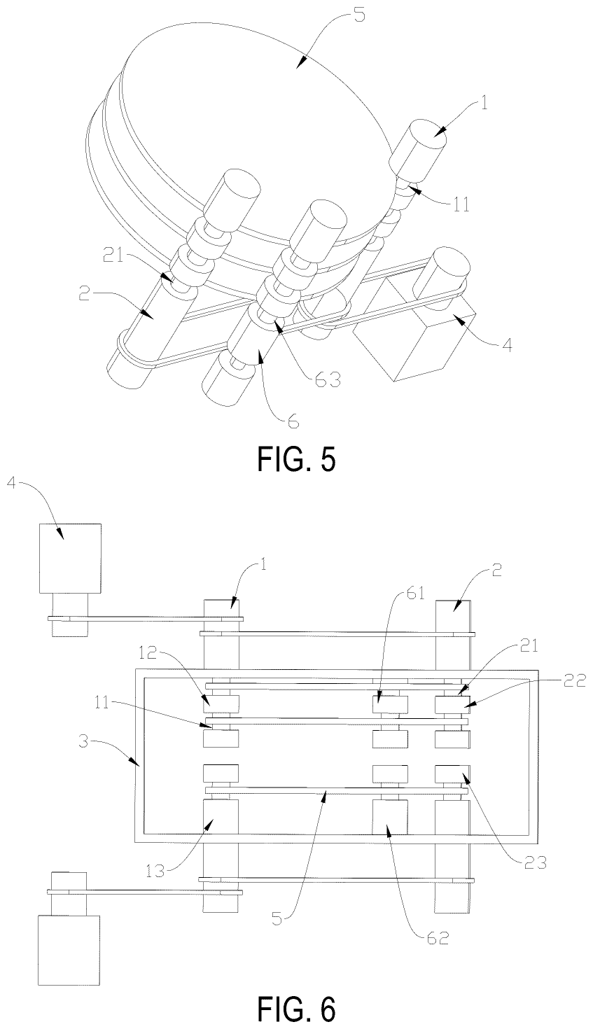

More specifically, in this embodiment, as shown in FIG. 1 to FIG. 5, the first driving shaft 1 and the second driving shaft 2 are powered by the same drive unit 4. That is, the rotation speeds of the first driving shaft 1 and the second driving shaft 2 are the same. The first driving shaft 1 and the second driving shaft 2 are connected to the driving unit 4 by motor direct drive, belt drive, etc., which is not specifically limited.

One end of the first driving shaft 1 is rotationally connected to a side wall of the cleaning tank 3 and the other end of the first driving shaft 1 is connected to the drive unit 4; the second driving shaft 2 is arranged in parallel with the first driving shaft 1, one end of the second driving shaft 2 is rotatably connected to a side wall of the cleaning tank 3, and the other end of the second driving shaft 2 is connected to the driving unit 4. Two ends of the driven shaft 6 are connected to the side walls of the cleaning tank 3.

In other embodiments, there may be an alternative of the above structure: one end of the first driving shaft 1 is connected to the drive unit 4 and the other end of the first driving shaft 1 is suspended in the cleaning tank 3 rather than being rotatably connected to a side wall of the cleaning tank 3; one end of the second driving shaft 2 is connected to the drive unit 4 and the other end of the second driving shaft 2 suspended in the cleaning tank 3 rather than being rotationally connected to a side wall of the cleaning tank 3 but is; one end of the driven shaft 6 is connected to a side wall of the cleaning tank 3 and the other end of the driven shaft 6 is suspended in the cleaning tank 3.

Of course, these features may also be combined. That is, in the same cleaning tank 3, one end of the first driving shaft 1 is connected to the drive unit 4 and the other end of the first driving shaft 1 is suspended in the cleaning tank 3; one end of the first driving shaft 1 is connected to the drive unit 4 and the other end of the first driving shaft 1 is connected to a side wall of the cleaning tank 3; one end of the second driving shaft 2 is connected to the drive unit 4 and the other end of the second driving shaft 2 is rotatably connected to a side wall of the cleaning tank 3; one end of the second driving shaft 2 is connected to the drive unit 4 and the other end of the second driving shaft 2 is suspended in the cleaning tank 3; one end of the driven shaft 6 is connected to a side wall of the cleaning tank 3 and the other end of the driven shaft 6 is suspended in the cleaning tank 3; two ends of the driven shaft 6 are both connected to the side walls of the cleaning tank 3; the first driving shaft 1 and the second driving shaft 2 are driven by the same drive unit 4; the first driving shaft 1 and the second driving shaft 2 are driven by different drive units 4; no driven shaft 6 is provided. These nine features may be combined at will without limitation. Three wafers 5 are respectively clamped in the three first clamping grooves 11 on the first driving shaft 1 and the three second clamping grooves 21 on the second driving shaft 2. When the first driving shaft 1 and the second driving shaft 2 rotate in the same direction, the three wafers 5 rotate simultaneously and are cleaned while rotating.

As shown in FIG. 4, the driven shaft 6 is located under the wafers 5 and between the first driving shaft 1 and the second driving shaft 2, and deviates from the center axis of the wafers 5. Compared with a solution where the driven shaft 6 is located on the center axis of the wafers 5, the solution of the invention maximizes the distance between the first driving shaft 1 and the second driving shaft 2, and under the premise of ensuring the stability of the wafers 5, the distance between the bottom of the cleaning tank 3 of the megasonic cleaning device 31 and the wafers 5 is shortest, thereby achieving a better cleaning effect.

In order to ensure the consistency of the cleaning effect of the wafers, each chemical solution in the cleaning liquid in each cleaning tank 3 needs complex closed-loop flow control to ensure the precise proportion of the cleaning liquid. Since multiple of wafers 5 are cleaned in the same cleaning tank 3, it can be ensured that each wafer 5 is in the cleaning liquid of the same proportion, thereby ensuring the cleaning consistency and reducing the liquid preparation cost. Moreover, compared with a solution where a plurality of cleaning tanks are provided and each tank has one wafer, the solution where multiple wafers 5 are placed in one cleaning tank 3 has the following advantages: the total volume of the cleaning liquid is smaller; and since multiple wafers 5 are placed in one cleaning tank 3, the distance between wafers 5 is smaller, allowing a set of robot arms to pick and place the plurality of wafers 5 at the same time.

### Embodiment 2

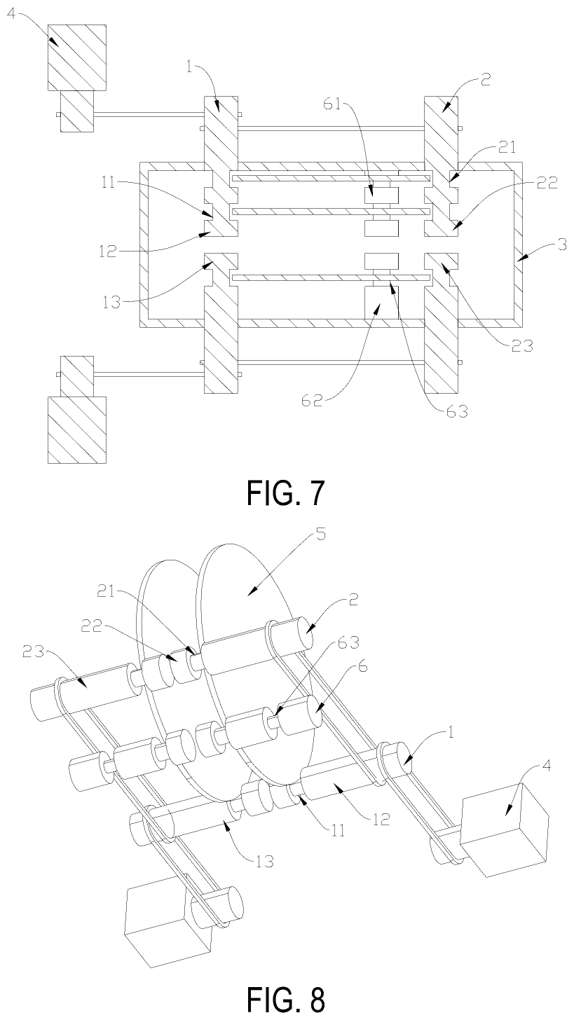

As shown in FIGS. 6 to 8, this embodiment differs from Embodiment 1 in the following aspect. In this embodiment, the first driving shaft 1 comprises a left shaft body 12 and a right shaft body 13 that are coaxially arranged, wherein adjacent ends of the left shaft body 12 and the right shaft body 13 are suspended; the second driving shaft 2 comprises a left shaft body 22 and a right shaft body 23 that are arranged coaxially, wherein adjacent ends of the left shaft body 22 and the right shaft body 23 are suspended; the left shaft body 12 of the first driving shaft 1 and the left shaft body 22 of the second driving shaft 2 are driven by a same drive unit 4 to rotate synchronously, and the right shaft body 13 of the first driving shaft 1 and the right shaft 23 of the second driving shaft 2 are driven by another drive unit 4 to rotate synchronously.

Therefore, the rotation speeds of the left shaft body 12 and the right shaft body 13 of the first driving shaft 1 may be different, and the rotation speeds of the left shaft body 22 and the right shaft body 23 of the second driving shaft 2 may be different.

The driven shaft 6 comprises a first shaft body 61 and a second shaft body 62 that are coaxially arranged. Adjacent ends of the first shaft body 61 and the second shaft body 62 are suspended.

A batch of wafers 5 may be placed between the first clamping grooves 11 of the left shaft body 12 of the first driving shaft 1 and the second clamping grooves 21 of the left shaft body 22 of the second driving shaft 2 and limited by the limiting grooves 63 of the first shaft body 61, and then the wafers 5 can be rotated and cleaned.

Another batch of wafers 5 may be placed between the first clamping grooves 11 of the right shaft body 13 of the first driving shaft 1 and the second clamping grooves 21 of the right shaft body 23 of the second driving shaft 2 and limited by the limiting grooves 63 of the second shaft body 62, and then the wafers 5 can be rotated and cleaned.

Therefore, the two batches of wafers 5 can be driven by different driving units 4 to rotate to be cleaned, and the cleaning and rotation speeds may be different, thereby achieving relatively independent cleaning speeds to adapt to different cleaning requirements.

Of course, these three features: the first driving shaft 1 comprises a left shaft body 12 and a right shaft body 13, the second driving shaft 2 comprises a left shaft body 22 and a right shaft body 23, and the driven shaft 6 comprises a first shaft body 61 and the second shaft body 62. may also be combined with the nine features in Embodiment 1 without limitation.

The above specific embodiments are used to explain the invention, rather than to limit the invention. Within the spirit of the invention and the scope of the claims, any modifications and changes made to the invention should fall within the scope of the invention.

1. An array-type megasonic cleaning device for cleaning wafers, comprising:
a cleaning tank (3) with cleaning liquid and a megasonic generating device (31) inside; and
a first driving shaft (1) and a second driving shaft (2) that are arranged in parallel with each other in the cleaning tank (3) and are capable of rotating circumferentially about their own center axes under the drive of a drive unit (4);
wherein the first driving shaft (1) and the second driving shaft (2) have an axial length of 60-350 mm;
at least two first clamping grooves (11) are formed on the first driving shaft (1) in a length direction, at least two second clamping grooves (21) are formed on the second driving shaft (2) in the length direction, and the second clamping grooves (21) are arranged corresponding to the first clamping grooves (11);
a plurality of wafers (5) are respectively placed by means of the cooperation of the first clamping grooves (11) and the second clamping grooves (21), and the first driving shaft (1) and the second driving shaft (2) are configured to be respectively located on two sides of a center axis of the wafers (5);
the first driving shaft (1) and the second driving shaft (2) rotate in a same direction, and then the plurality of wafers (5) are driven, by friction, to rotate simultaneously to be cleaned.

2. The array-type megasonic cleaning device for cleaning wafers according to claim 1, further comprising a driven shaft (6) provided with at least two limiting grooves (63), wherein the limiting grooves (63) are located in a same vertical plane as the first clamping grooves (11) and the second clamping grooves (21), and edges of the wafers (5) fall into the limiting grooves (63).

3. The array-type megasonic cleaning device for cleaning wafers according to claim 2, wherein the driven shaft (6) is configured to be located under the wafers (5) and deviates from the center axis of the wafers (5).

4. The array-type megasonic cleaning device for cleaning wafers according to claim 2, wherein gaps are formed between inner walls of the limiting grooves (63) and the wafers (5).

5. The array-type megasonic cleaning device for cleaning wafers according to claim 2, wherein side surfaces of the limiting grooves (63) are in contact with the wafers to drive the driven shaft (6) to rotate; the driven shaft (6) is externally connected to a rotation speed detection unit (64) to monitor a rotation speed of the wafers (5); gaps are formed between bottom surfaces of the limiting grooves (63) and the wafers (5).

6. The array-type megasonic cleaning device for cleaning wafers according to claim 1, wherein rotation speeds of the first driving shaft (1) and the second driving shaft (2) are the same.

7. The array-type megasonic cleaning device for cleaning wafers according to claim 1, wherein one end of the first driving shaft (1) and/or the second driving shaft (2) is connected to a side wall of the cleaning tank (3) and the other end of the first driving shaft (1) and/or the second driving shaft (2) is connected to the drive unit (4); alternatively, one end of the first driving shaft (1) and/or the second driving shaft (2) is suspended in the cleaning tank (3) and the other end of the first driving shaft (1) and/or the second driving shaft (2) is connected to the drive unit (4).

8. The array-type megasonic cleaning device for cleaning wafers according to claim 2, wherein the driven shaft (6) comprises a first shaft body (61) and a second shaft body (62), the first shaft body (61) and the second shaft body (62) are coaxially arranged, and adjacent ends of the first shaft body (61) and the second shaft body (62) are suspended.

9. The array-type megasonic cleaning device for cleaning wafers according to claim 1, wherein the first driving shaft (1) and/or the second driving shaft (2) comprises a left shaft body and a right shaft body, and the left shaft body and the right shaft body are coaxially arranged and driven by the drive unit (4) to rotate respectively.

10. The array-type megasonic cleaning device for cleaning wafers according to claim 9, wherein rotation speeds of the left shaft body and the right shaft body are different.
